(19) United States
(12) Patent Application Publication
(10) Pub. No.: US 2013/0270638 A1
(43) Pub. Date: Oct. 17, 2013

(54) STRAINED SOI FINFET ON EPITAXIALLY GROWN BOX

(71) Applicants: Thomas N. Adam, Albany, NY (US); Kangguo Cheng, Albany, NY (US); Ali Khakifirooz, Albany, NY (US); Alexander Reznicek, Albany, NY (US); Raghavasimhan Sreenivasan, Albany, NY (US)

(72) Inventors: Thomas N. Adam, Albany, NY (US); Kangguo Cheng, Albany, NY (US); Ali Khakifirooz, Albany, NY (US); Alexander Reznicek, Albany, NY (US); Raghavasimhan Sreenivasan, Albany, NY (US)

(73) Assignee: INTERNATIONAL BUSINESS MACHINES CORPORATION, ARMONK, NY (US)

(21) Appl. No.: 13/445,959

(22) Filed: Apr. 13, 2012

(51) Int. Cl. H01L 29/78; H01L 21/336

(52) U.S. Cl. 257/347; 438/151; 257/E29.255; 257/E21.409

(57) ABSTRACT

A semiconductor structure includes an epitaxial insulator layer located on a substrate. A fin structure is located on the epitaxial insulator layer, where at least one epitaxial source-drain region having an embedded stressor is located on the epitaxial insulator layer and abuts at least one sidewall associated with the fin structure. The epitaxial source-drain region having the embedded stressor provides stress along the fin structure such that the provided stress is based on a lattice mismatch between the epitaxial source-drain region, and both the epitaxial insulator layer and the one side-wall associated with the fin structure.

### BACKGROUND

a. Field of Invention

The present invention generally relates to semiconductor devices, and more particularly, to structures, fabrication methods, and design structures for strained FinFet Devices.

b. Background of Invention

A fin metal-oxide-semiconductor field effect transistor (FinMOSFET, or finFET) provides solutions to metal-oxide-semiconductor field effect transistor (MOSFET) scaling problems at and below, for example, the 45 nm node of semiconductor technology. A finFET comprises at least one narrow (preferably <30 nm wide) semiconductor fin gated on at least two opposing sides of each of the at least one semiconductor fin. FinFET structures may typically be formed on either a semiconductor-on-insulator (SOI) substrate or a bulk semiconductor substrate.

A feature of a finFET is a gate electrode located on at least two sides of the channel formed along the longitudinal direction of the fin. Due to the advantageous feature of full depletion in the fin structure a finFET, the increased number of sides (e.g., two or three) on which the gate electrode controls the channel of the finFET enhances the controllability of the channel in a finFET compared to a planar MOSFET. The improved control of the channel allows smaller device dimensions with less short channel effects as well as larger electrical current that can be switched at high speeds. A finFET device has faster switching times, equivalent or higher current density, and much improved short channel control than mainstream CMOS technology utilizing similar critical dimensions.

In addition to the above-mentioned characteristics of finFET devices, further enhancements may include the introduction of longitudinal stress (i.e., compressive or tensile) to the channel region of the finFet in order to improve carrier mobility and subsequent increased finFET performance. Forming finFET devices on SOI substrates provide several characteristics such as low capacitance between the device source/drain regions and the device substrate, no trench isolation, no punchthrough stop doping, and little to no fin height variation. However, the achievable longitudinal stress (i.e., compressive or tensile) to the channel region of finFets formed on SOI substrates may be less compared to that of finFET devices formed on bulk semiconductor substrates.

### BRIEF SUMMARY

According to at least one exemplary embodiment, a method of forming a semiconductor structure on a substrate may include forming an epitaxial insulator layer over the substrate, forming a semiconductor layer over the epitaxial insulator layer, forming a fin structure at least partially from the semiconductor layer and over the epitaxial insulator layer, and forming at least one epitaxial source/drain (S/D) region having an embedded stressor on the epitaxial insulator layer and the side wall surface of the fin structure. The epitaxial S/D region further includes an embedded stressor for providing either compressive or tensile stress along the fin structure.

According to another exemplary embodiment, a semiconductor structure may include an epitaxial insulator layer located on a substrate. A fin structure is located on the epitaxial insulator layer, where at least one epitaxial source/drain (S/D) region having an embedded stressor is located on the epitaxial insulator layer and abuts at least one sidewall associated with the fin structure. The epitaxial S/D region may include an embedded stressor which provides stress (e.g., tensile or compressive) along the fin structure such that the provided stress is based on a lattice mismatch between the epitaxial S/D region having the embedded stressor, and both the epitaxial insulator layer and the side-wall associated with the fin structure.

### BRIEF DESCRIPTION OF THE SEVERAL VIEWS OF THE DRAWINGS

FIG. 1 is a perspective view of a semiconductor structure used in the fabrication of a finFET, according to at least one exemplary embodiment;

FIG. 2 is a perspective view of a semiconductor structure illustrating the formation of a fin structure from the semiconductor structure of FIG. 1, according to at least one exemplary embodiment;

FIG. 3 is a perspective view of a semiconductor structure illustrating the formation of a gate structure over the fin structure of FIG. 2, according to at least one exemplary embodiment;

FIG. 4 is a perspective view of a semiconductor structure illustrating the formation of a gate spacer for the gate structure of FIG. 3, according to at least one exemplary embodiment;

FIG. 5 is a perspective view of a semiconductor structure illustrating the formation of strained raised drain/source regions adjacent the gate spacer and fin structure of FIG. 4, according to at least one exemplary embodiment; and

FIG. 6 is a flow diagram of a design process used in semiconductor design, manufacture, and/or test.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

The following described and illustrated example finFET structure is formed on a silicon-on-insulator (SOI) substrate that enables the provision of requisite stress on the finFET channel region in order to improve device performance (e.g., carrier mobility).

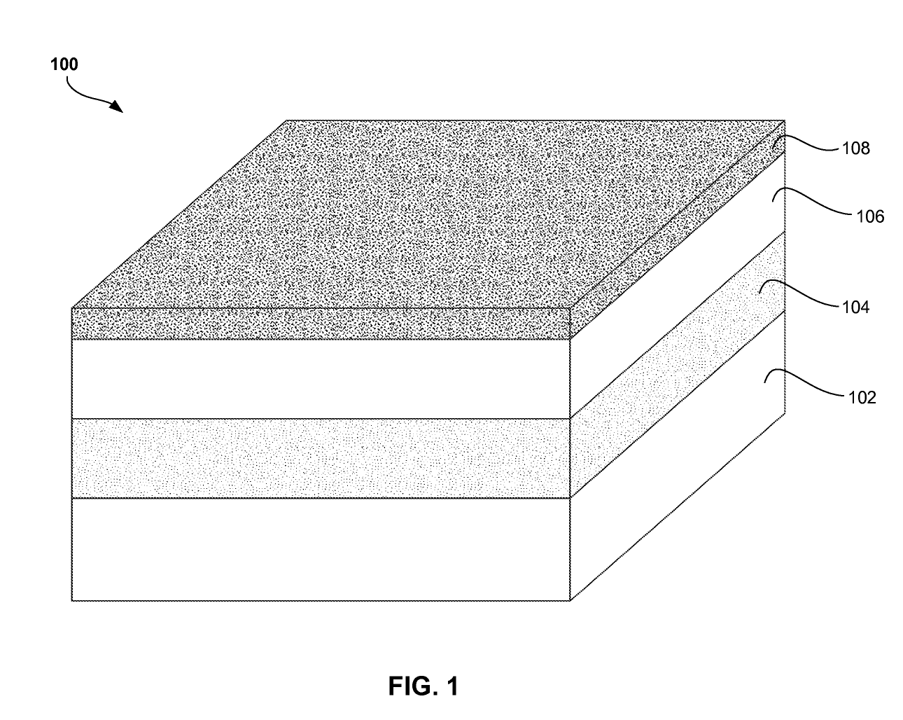

Referring to FIG. 1, a SOI semiconductor structure 100 for fabricating a strained finFET device according to an exemplary embodiment is provided. Semiconductor structure 100 may include a semiconductor substrate 102, an epitaxial insulator layer 104, an epitaxial semiconductor layer 106, and a hardmask layer 108.

For example, the epitaxial insulator layer 104 may be formed from gadolinium oxide (Gd₂O₃), strontium titanate (SrTiO₃), or barium titanate (BaTiO₃) materials having a thickness similar to that of a buried oxide (BOX) layer (e.g., 145 nm). The thickness of the epitaxial insulator layer 104 may, however, generally vary according to the device structure that is manufactured and the device characteristics desired. For example, the thickness of the epitaxial insulator layer 104 may be in the range of about 5-1000 nanometers (nm), with a preferred thickness of approximately 50-100 nm. The epitaxial insulator layer 104 may be formed from a crystalline structure which has the same lattice constant as the underlying (i.e., lattice constant) semiconductor substrate 102 and the top formed epitaxial semiconductor layer 106. Thus, lattice information is preserved throughout the substrate 102, epitaxial insulator 104, and epitaxial insulator 106 layers.

In a formed SOI structure such as semiconductor structure 100, an amorphous oxide insulator layer such as silicon dioxide (SiO₂) may be replaced by an epitaxial insulator layer (e.g., Gd₂O₃) having a crystalline structure, since it may not be possible to grow a single crystalline material on top of an amorphous layer. In contrast, by growing the epitaxial SiGe stressor material over a crystalline oxide structure such as gadolinium oxide (Gd₂O₃), lattice stress is transferred from the SiGe to the underlying Gd₂O₃ material (i.e., epitaxial insulator layer), which has a different lattice constant to that of SiGe.

Accordingly, the epitaxial insulator 104 provides the necessary isolation required by an oxide layer in forming an SOI structure, while also providing a template or base for growing epitaxial materials that are intended to induce stress with respect to other structures formed within or over the epitaxial insulator 104. The following paragraphs describe an exemplary embodiment of a finFET device fabricated from semiconductor structure 100, whereby the epitaxial insulator layer 104 facilitates the epitaxial growth of stressor materials for the formation of raised source-drain (S/D) structures. A raised source-drain (S/D) structure may operationally behave as either a source region or a drain region of the finFET device based on the manner in which the device is utilized.

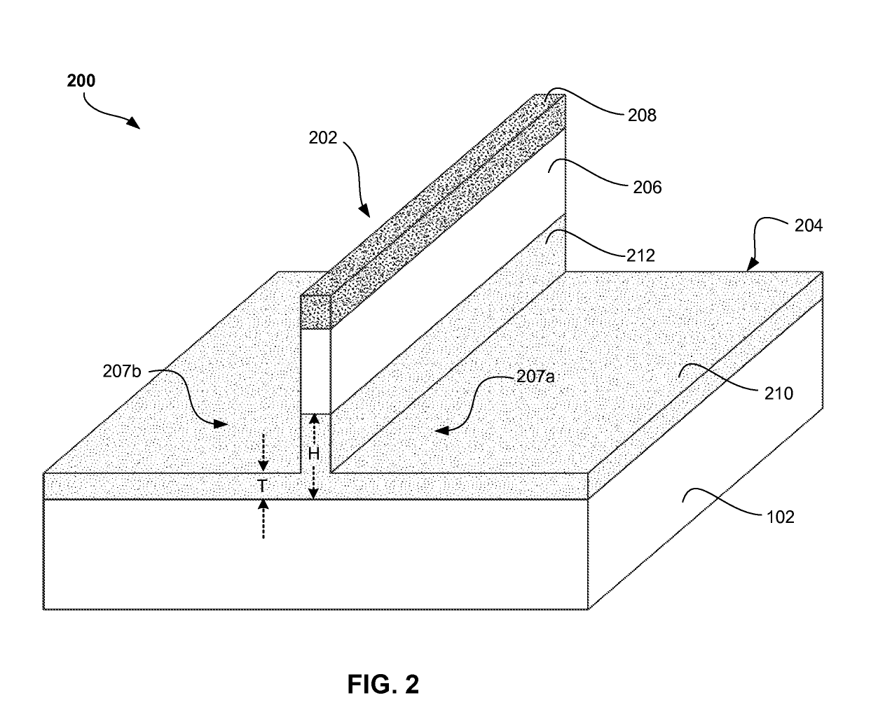

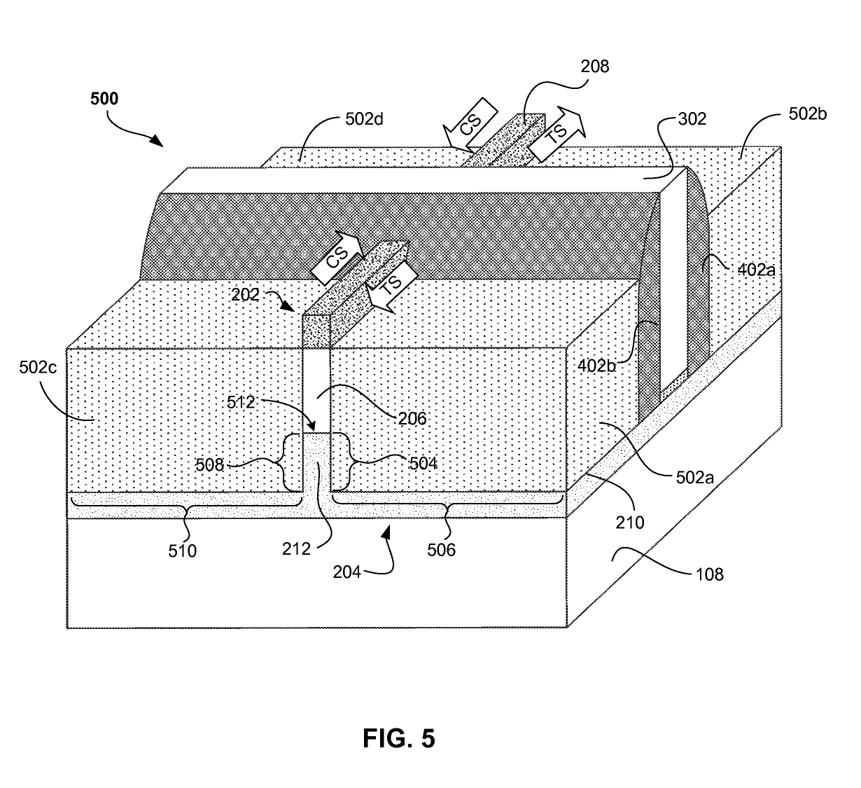

As further illustrated in FIG. 1, the hardmask layer 108 (e.g., silicon nitride; Si₃N₄) may be used in the patterning and etching process for manufacturing a finFET device according to one embodiment of the invention. Referring to FIG. 2, structure 200 illustrates the formation of a fin structure 202 based on the etching and patterning of structure 100 (FIG. 1). By patterning hardmask layer 108 (FIG. 1), following the etching process, the regions of layers 104 and 106 (FIG. 1) not protected by hardmask region 208 are removed to form a fin structure 202 that includes epitaxial insulator region 212, epitaxial semiconductor region 206, and the hardmask region 208. The etching process also creates a recess area 207a, 207b in the epitaxial insulator layer 204, which serves both as an SOI structure oxide layer and a base layer 210 or template for the growth of, for example, epitaxial stressor materials (e.g., see FIG. 5) utilized for the formation of device structures such as raised drain/source (S/D) regions in finFET devices. The fin 202 may have a width of about 2-100 nm, preferably 4-40 nm. In a preferred embodiment, fin 202 may be fabricated to include a width in the range of approximately 6-15 nm. Fin structure 202 may have a height of about 5-200 nm, preferably 10-80 nm. In a preferred embodiment, fin 202 may be fabricated to include a height in the range of approximately 20-40 nm. The epitaxial insulator 204 may have a thickness (T) in the range of 5-1000 nm, preferably 10-200 nm. In a preferred embodiment, the epitaxial insulator layer 204 thickness may be about 15-50 nm. The epitaxial insulator 204 may have a height (H) in the range of 10-1000 nm, preferably 20-200 nm. In a preferred embodiment, the epitaxial insulator layer 204 height may be about 50-100 nm.

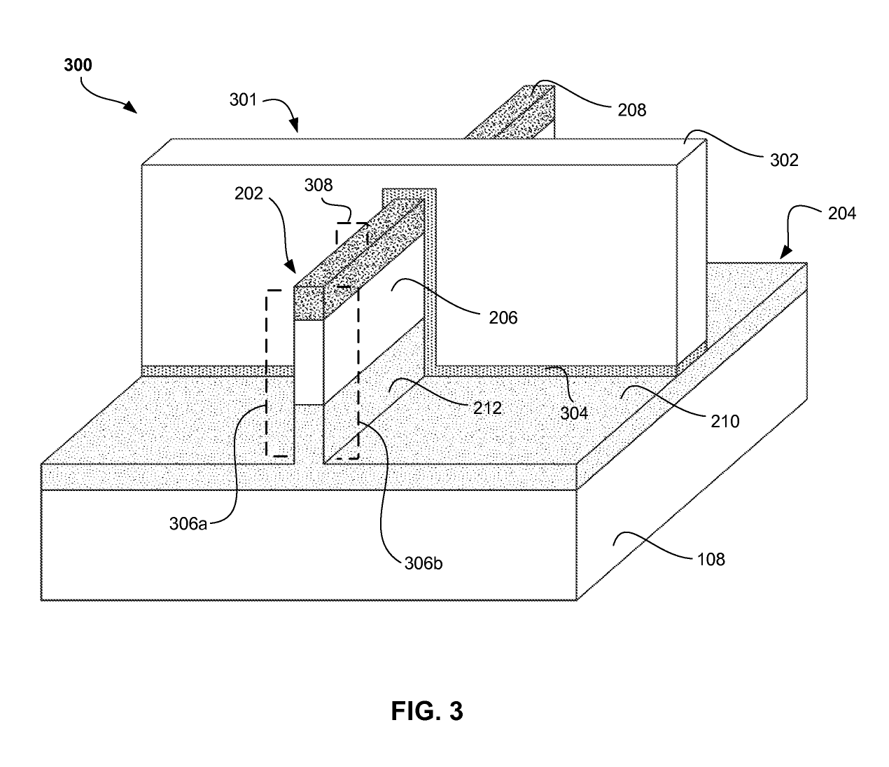

Referring to FIG. 3, structure 300 illustrates the formation of a gate structure 301 over the created fin 202 of structure 200 (FIG. 2). Gate structure 301 includes gate dielectric 304 and gate electrode 302. The formation of gate structure 301 may be realized by either a gate-first process or a gate-last process utilizing a dummy-gate. In some embodiments, for example, during the formation of a tri-gate structure, the hardmask region 208 may be removed. Alternatively, in other embodiments, as illustrated in FIGS. 3-5, the hardmask 208 may be kept in place. The gate dielectric 304 is formed over both the sidewalls 306a, 306b and top surface 308 of the fin 202, and the base layer 210 of the epitaxial insulator 204. Dielectric 304 may include a high-k dielectric material having a dielectric constant greater than, for example, 3.9, which is the dielectric constant of silicon oxide. The high-k dielectric material may include a dielectric metal oxide. In some implementations, a high-k material that has a dielectric constant in the range of about 4.0-8.0 may be utilized. Exemplary high-k dielectric materials may include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, or Y₂OₓN_{y}. In other implementations, a silicon nitride (Si₃N₄) dielectric having a dielectric constant of about 7.5 may be used as a gate dielectric. Gate dielectric 304 may also include a multi-layer of SiO₂, SiON, SiN, and a high-k dielectric material, including but not limited, to hafnium oxide (HfO₂), aluminum oxide (Al₂O₃), lantanum oxide (La₂O₃), zircunium oxide (ZrO₂), and their respective silicates. The thickness of the gate dielectric 304 may be in the range of 1.0 nm-5.0 nm. The gate electrode 302 may include metals such as TiN, TaN, W, WN, TaAlN, Al, Au, Ag, or a stacked combination of such metals. Gate electrode 302 may also include a Poly-Silicon layer located on top of a metal material, whereby the top of the Poly-Silicon layer may be silicided. Gate electrode 304 may have a thickness approximately in the range of 20-100 nm and a length in the range of about 10-250 nm, although lesser and greater thicknesses and lengths may also be contemplated.

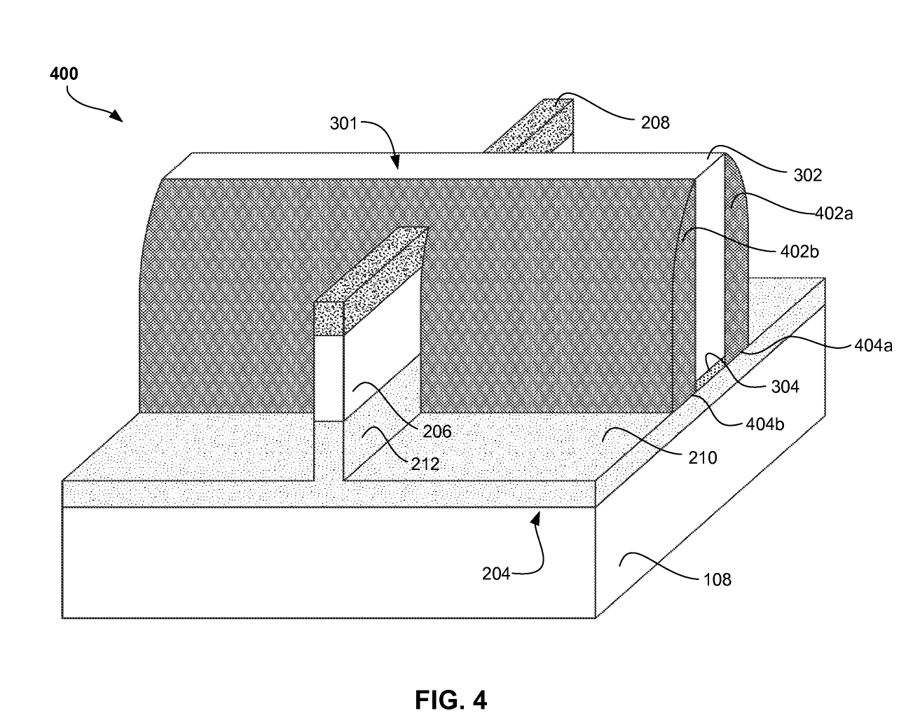

Referring to FIG. 4, structure 400 illustrates the formation of a gate spacer 402a, 402b. The gate spacer 402a, 402b is formed on the sidewalls of the gate electrode 302 by deposition of a dielectric layer. The dielectric layer may be formed, for example, by chemical vapor deposition (CVD) of a dielectric material. The gate spacer 402a, 402b may laterally surround each gate electrode 302 if, for example, multiple gate electrodes are present in a semiconductor structure. Also, the gate spacer 402a, 402b electrically isolates the gate electrode 302 from electrical cross-talk that may occur with electrical contacts that are formed with respect to the epitaxially grown S/D regions (see FIG. 5).

For example, the dielectric materials used to form gate spacer 402a, 402b may include silicon oxide, silicon nitride, or silicon oxynitride. The thickness of the gate spacer 402a, 402b, as measured at the respective bases 404a, 404b of the gate spacer 402a, 402b, may be in the range of about 2-100 nm, and preferably from about 6-10 nm, although lesser and greater thicknesses may also be contemplated.

FIG. 5 illustrates a semiconductor structure 500 showing the formation of strained raised drain/source regions 502a, 502b, 502c, 502d adjacent the gate spacer 402a, 402b and fin structure 202. Source/drain region 502a is epitaxially grown over the base layer 210 of epitaxial insulator layer 204. As illustrated, the epitaxially grown source/drain region 502a is also formed over sidewall 306b (FIG. 3) of the fin 202, extending longitudinally across both the epitaxial insulator portion 212 and epitaxial semiconductor region 206 of the fin 202. A side portion of source/drain region 502a is epitaxially grown over surface 504 of the epitaxial insulator portion 212 of fin structure 202. A bottom surface portion of the source/drain region 502a is epitaxially grown over surface 506 of the base layer 210 of epitaxial insulator 204. Due to a lattice mismatch between the epitaxially grown source/drain region 502a and the epitaxial insulator 204, crystalline stress is exhibited at the interface between the epitaxially grown source/drain region 502a, and both surface 506 of the base layer 210 of epitaxial insulator 204 and surface 504 of the epitaxial insulator portion 212 of fin structure 202. The nature of the stress (i.e., tensile or compressive) depends on the material used to form the raised drain/source regions.

For example, for a pFET finFET device, the epitaxially grown source/drain region 502a may include a silicon germanium (SiGe) type material, where the atomic concentration of germanium (Ge) may range from about 10-80%, preferably from about 20-60%. In a preferred exemplary embodiment, the concentration of germanium (Ge) may be 50%. SiGe provides a compressive strain. Thus, a SiGe epitaxially grown source/drain region 502a exerts a longitudinal compressive strain in the direction of arrow CS with respect to the fin structure 202. More specifically, the SiGe source/drain region 502a induces a compressive stress on surface 504 of the epitaxial insulator portion 212 of fin structure 202. The compressive stress on surface 504 of the epitaxial insulator portion 212 of fin structure 202 provides compressive stress to the channel region (not shown) of the fin 202, which produces, for example, enhanced carrier mobility and increased drive current. Additionally, compressive stress to the channel region is also provided by the SiGe source/drain region 502a inducing a compressive stress on both the fin's 202 epitaxial semiconductor region 206 and the base 210 of the epitaxial insulator 204. Dopants such as boron may be incorporated into the SiGe source/drain region 502a by in-situ doping. The percentage of boron may range from 1E19 cm⁻³ to 2E21 cm⁻³, preferably 1E20 cm⁻³ to 1E21 cm⁻³. In a preferred exemplary embodiment, the percentage of boron may range from 4E20 cm⁻³ to 7E20 cm⁻³.

For example, for a nFET finFET device, the epitaxially grown source/drain region 502a may include a carbon doped Silicon (Si:C) type material, where the atomic concentration of carbon (C) may range from about 0.4-3.0%, preferably from about 0.5-2.5%. In a preferred exemplary embodiment, the concentration of carbon (C) may be approximately 1.5-2.2%. Si:C provides a tensile strain. Thus, a Si:C epitaxially grown source/drain region 502a exerts a longitudinal tensile strain in the direction of arrow TS with respect to the fin structure 202. More specifically, the Si:C source/drain region 502a induces a tensile stress on surface 504 of the epitaxial insulator portion 212 of fin structure 202. The tensile stress on surface 504 of the epitaxial insulator portion 212 of fin structure 202 provides tensile stress to the channel region (not shown) of the fin 202, which produces, for example, enhanced carrier mobility and increased drive current. Additionally, tensile stress to the channel region is also provided by the SiGe source/drain region 502a inducing a compressive stress on both the fin's 202 epitaxial semiconductor region 206 and the base 210 of the epitaxial insulator 204. Dopants such as phosphorous or arsenic may be incorporated into the Si:C source/drain region 502a by in-situ doping. The percentage of phosphorous or arsenic may range from 1E19 cm⁻³ to 2E21 cm⁻³, preferably 1E20 cm⁻³ to 1E21 cm⁻³. In a preferred exemplary embodiment, the percentage of boron may range from 4E20 cm⁻³ to 7E20 cm⁻³.

Similarly, source/drain region 502c is epitaxially grown over the base layer 210 of epitaxial insulator layer 204. As illustrated, the epitaxially grown source/drain region 502c is also formed over sidewall 306a (FIG. 3) of the fin 202, also longitudinally extending across both the epitaxial insulator portion 212 and epitaxial semiconductor region 206 of the fin 202. A side portion of source/drain region 502c is epitaxially grown over surface 508 of the epitaxial insulator portion 212 of fin structure 202. A bottom surface portion of the source/drain region 502c is epitaxially grown over surface 510 of the base layer 210 of epitaxial insulator 204. Due to a lattice mismatch between the epitaxially grown source/drain region 502c and the epitaxial insulator 204, crystalline stress is exhibited at the interface between the epitaxially grown source/drain region 502c, and both surface 510 of the base layer 210 of epitaxial insulator 204 and surface 508 of the epitaxial insulator portion 212 of fin structure 202. The nature of the stress (i.e., tensile or compressive) depends on the material used to form the raised drain/source regions.

For example, for a pFET finFET device, the epitaxially grown source/drain region 502c may include a silicon germanium (SiGe) type material, where the atomic concentration of germanium (Ge) may range from about 10-80%, preferably from about 20-60%. In a preferred exemplary embodiment, the concentration of germanium (Ge) may be 50%. SiGe provides a compressive strain. Thus, a SiGe epitaxially grown source/drain region 502c exerts a longitudinal compressive strain in the direction of arrow CS with respect to the fin structure 202. More specifically, the SiGe source/drain region 502c induces a compressive stress on surface 508 of the epitaxial insulator portion 212 of fin structure 202. The compressive stress on surface 508 of the epitaxial insulator portion 212 of fin structure 202 also provides compressive stress to the channel region (not shown) of the fin 202, which produces, for example, enhanced carrier mobility and increased drive current. Additionally, compressive stress to the channel region is also provided by the SiGe source/drain region 502c inducing a compressive stress on both the fin's 202 epitaxial semiconductor region 206 and the base 210 of the epitaxial insulator 204. Dopants such as boron may also be incorporated into the SiGe source/drain region 502c by in-situ doping. The percentage of boron may range from 1E19 cm⁻³ to 2E21 cm⁻³, preferably 1E20 cm⁻³ to 1E21 cm⁻³. In a preferred exemplary embodiment, the percentage of boron may range from 4E20 cm⁻³ to 7E20 cm⁻³.

For example, for a nFET finFET device, the epitaxially grown source/drain region 502c may include a carbon doped silicon (Si:C) type material, where the atomic concentration of carbon (C) may range from about 0.4-3.0%, preferably from about 0.5-2.5%. In a preferred exemplary embodiment, the concentration of carbon (C) may be approximately 1.5-2.2%. Si:C provides a tensile strain. Thus, a Si:C epitaxially grown source/drain region 502c exerts a longitudinal tensile strain in the direction of arrow TS with respect to the fin structure 202. More specifically, the Si:C source/drain region 502c induces a tensile stress on surface 508 of the epitaxial insulator portion 212 of fin structure 202. The tensile stress on surface 508 of the epitaxial insulator portion 212 of fin structure 202 provides tensile stress to the channel region (not shown) of the fin 202, which produces, for example, enhanced carrier mobility and increased drive current. Additionally, tensile stress to the channel region is also provided by the SiGe source/drain region 502c inducing a compressive stress on both the fin's 202 epitaxial semiconductor region 206 and the base 210 of the epitaxial insulator 204. Dopants such as phosphorous or arsenic may be incorporated into the Si:C source/drain region 502c by in-situ doping. The percentage of phosphorous or arsenic may range from 1E19 cm⁻³ to 2E21 cm⁻³, preferably 1E20 cm⁻³ to 1E21 cm⁻³. In a preferred exemplary embodiment, the percentage of Boron may range from 4E20 cm⁻³ to 7E20 cm⁻³.

Source/drain region 502b is also epitaxially grown over the base layer 210 of epitaxial insulator layer 204. The epitaxially grown source/drain region 502b is also formed over sidewall 306b (FIG. 3) of the fin 202, and extends longitudinally across both the epitaxial insulator portion 212 and epitaxial semiconductor region 206 of the fin 202. A side portion of source/drain region 502b is epitaxially grown over surface 504 of the epitaxial insulator portion 212 of fin structure 202. A bottom surface portion of the source/drain region 502b is epitaxially grown over surface 506 of the base layer 210 of epitaxial insulator 204. Due to a lattice mismatch between the epitaxially grown source/drain region 502b and the epitaxial insulator 204, crystalline stress is exhibited at the interface between the epitaxially grown source/drain region 502b, and both surface 506 of the base layer 210 of epitaxial insulator 204 and surface 504 of the epitaxial insulator portion 212 of fin structure 202. The nature of the stress (i.e., tensile or compressive) depends on the material used to form the raised drain/source regions.

As previously described, for a pFET finFET device, the epitaxially grown source/drain region 502b may include a silicon germanium (SiGe) type material, where the atomic concentration of germanium (Ge) may range from about 10-80%, preferably from about 20-60%. In a preferred exemplary embodiment, the concentration of germanium (Ge) may be 50%. SiGe provides a compressive strain. Thus, a SiGe epitaxially grown source/drain region 502b exerts a longitudinal compressive strain in the direction of arrow CS with respect to the fin structure 202. More specifically, the SiGe source/drain region 502b induces a compressive stress on surface 506 of the epitaxial insulator portion 212 of fin structure 202. The compressive stress on surface 506 of the epitaxial insulator portion 212 of fin structure 202 also provides compressive stress to the channel region (not shown) of the fin 202, which produces, for example, enhanced carrier mobility and increased drive current. Additionally, compressive stress to the channel region is also provided by the SiGe source/drain region 502b inducing a compressive stress on both the fin's 202 epitaxial semiconductor region 206 and the base 210 of the epitaxial insulator 204. Dopants such as boron may also be incorporated into the SiGe source/drain region 502b by in-situ doping. The percentage of boron may range from 1E19 cm⁻³ to 2E21 cm⁻³, preferably 1E20 cm⁻³ to 1E21 cm⁻³. In a preferred exemplary embodiment, the percentage of boron may range from 4E20 cm⁻³ to 7E20 cm⁻³.

Also, for a nFET finFET device, the epitaxially grown source/drain region 502b may include a carbon doped silicon (Si:C) type material, where the atomic concentration of carbon (C) may range from about 0.4-3.0%, preferably from about 0.5-2.5%. In a preferred exemplary embodiment, the concentration of carbon (C) may be approximately 1.5-2.2%. Si:C provides a tensile strain. Thus, a Si:C epitaxially grown source/drain region 502b exerts a longitudinal tensile strain in the direction of arrow TS with respect to the fin structure 202. More specifically, the Si:C source/drain region 502b induces a tensile stress on surface 506 of the epitaxial insulator portion 212 of fin structure 202. The tensile stress on surface 506 of the epitaxial insulator portion 212 of fin structure 202 provides tensile stress to the channel region (not shown) of the fin 202, which produces, for example, enhanced carrier mobility and increased drive current. Additionally, tensile stress to the channel region is also provided by the SiGe source/drain region 502b inducing a compressive stress on both the fin's 202 epitaxial semiconductor region 206 and the base 210 of the epitaxial insulator 204. Dopants such as phosphorous or arsenic may be incorporated into the Si:C source/drain region 502b by in-situ doping. The percentage of phosphorous or arsenic may range from 1E19 cm⁻³ to 2E21 cm⁻³, preferably 1E20 cm⁻³ to 1E21 cm⁻³. In a preferred exemplary embodiment, the percentage of Boron may range from 4E20 cm⁻³ to 7E20 cm⁻³.

Similarly, source/drain region 502d is epitaxially grown over the base layer 210 of epitaxial insulator layer 204. As illustrated, the epitaxially grown source/drain region 502d is also formed over sidewall 306a (FIG. 3) of the fin 202, also extending longitudinally across both the epitaxial insulator portion 212 and epitaxial semiconductor region 206 of the fin 202. A side portion of source/drain region 502d is epitaxially grown over surface 508 of the epitaxial insulator portion 212 of fin structure 202. A bottom surface portion of the source/drain region 502d is epitaxially grown over surface 510 of the base layer 210 of epitaxial insulator 204. Due to a lattice mismatch between the epitaxially grown source/drain region 502d and the epitaxial insulator 204, crystalline stress is exhibited at the interface between the epitaxially grown source/drain region 502d, and both surface 510 of the base layer 210 of epitaxial insulator 204 and surface 508 of the epitaxial insulator portion 212 of fin structure 202. The nature of the stress (i.e., tensile or compressive) depends on the material used to form the raised drain/source regions.

For example, for a pFET finFET device, the epitaxially grown source/drain region 502d may include a silicon germanium (SiGe) type material, where the atomic concentration of germanium (Ge) may range from about 10-80%, preferably from about 20-60%. In a preferred exemplary embodiment, the concentration of germanium (Ge) may be 50%. SiGe provides a compressive strain. Thus, a SiGe epitaxially grown source/drain region 502d exerts a longitudinal compressive strain in the direction of arrow CS with respect to the fin structure 202. More specifically, the SiGe source/drain region 502d induces a compressive stress on surface 508 of the epitaxial insulator portion 212 of fin structure 202. The compressive stress on surface 508 of the epitaxial insulator portion 212 of fin structure 202 also provides compressive stress to the channel region (not shown) of the fin 202, which produces, for example, enhanced carrier mobility and increased drive current. Additionally, compressive stress to the channel region is also provided by the SiGe source/drain region 502d inducing a compressive stress on both the fin's 202 epitaxial semiconductor region 206 and the base 210 of the epitaxial insulator 204. Dopants such as boron may also be incorporated into the SiGe source/drain region 502d by in-situ doping. The percentage of boron may range from 1E19 cm⁻³ to 2E21 cm⁻³, preferably 1E20 cm⁻³ to 1E21 cm⁻³. In a preferred exemplary embodiment, the percentage of boron may range from 4E20 cm⁻³ to 7E20 cm⁻³.

For example, for a nFET finFET device, the epitaxially grown source/drain region 502d may include a carbon doped silicon (Si:C) type material, where the atomic concentration of carbon (C) may range from about 0.4-3.0%, preferably from about 0.5-2.5%. In a preferred exemplary embodiment, the concentration of carbon (C) may be approximately 1.0-2.2%. Si:C provides a tensile strain. Thus, a Si:C epitaxially grown source/drain region 502d exerts a longitudinal tensile strain in the direction of arrow TS with respect to the fin structure 202. More specifically, the Si:C source/drain region 502d induces a tensile stress on surface 508 of the epitaxial insulator portion 212 of fin structure 202. The tensile stress on surface 508 of the epitaxial insulator portion 212 of fin structure 202 provides tensile stress to the channel region (not shown) of the fin 202, which produces, for example, enhanced carrier mobility and increased drive current. Additionally, tensile stress to the channel region is also provided by the SiGe source/drain region 502d inducing a compressive stress on both the fin's 202 epitaxial semiconductor region 206 and the base 210 of the epitaxial insulator 204. Dopants such as phosphorous or arsenic may be incorporated into the Si:C source/drain region 502d by in-situ doping. The percentage of phosphorous or arsenic may range from 1E19 cm⁻³ to 2E21 cm⁻³, preferably 1E20 cm⁻³ to 1E21 cm⁻³. In a preferred exemplary embodiment, the percentage of Boron may range from 4E20 cm⁻³ to 7E20 cm⁻³.

As the illustrative embodiment of FIG. 5 depicts, the fin structure 202 includes both the epitaxial insulator portion 212 and the epitaxial semiconductor region 206. In some embodiments, the fin structure 202 may include only the epitaxial semiconductor region 206. In such an embodiment, the base or bottom surface of the fin 202 may be formed by epitaxial insulator strip 512. Thus, the etching (e.g., RIE) process selectively removes only the desired regions of the hardmask 108 (FIG. 1) and the epitaxially grown semiconductor layer 106 (FIG. 1) without encroaching into the epitaxial insulator layer 104 (FIG. 1). Accordingly, no recesses 207a, 207b (FIG. 2) are created within the epitaxial insulator layer 104 (FIG. 1). Since the bottom surface portions of the source/drain regions are epitaxially grown over the surface of the epitaxial insulator 104, due to the lattice mismatch between the epitaxially grown source/drain regions and the epitaxial insulator layer 104, crystalline stress is exhibited at the interface between the epitaxially grown source/drain regions and the epitaxial insulator layer 104. Therefore, the stress that is induced by the epitaxially grown source/drain regions on the epitaxial insulator layer 104 will be transferred to one or more fin structures that are created on the epitaxial insulator layer 104. The resulting stress on the fin structure or structures causes channel stress in the finFET device, which enhances then device's performance.

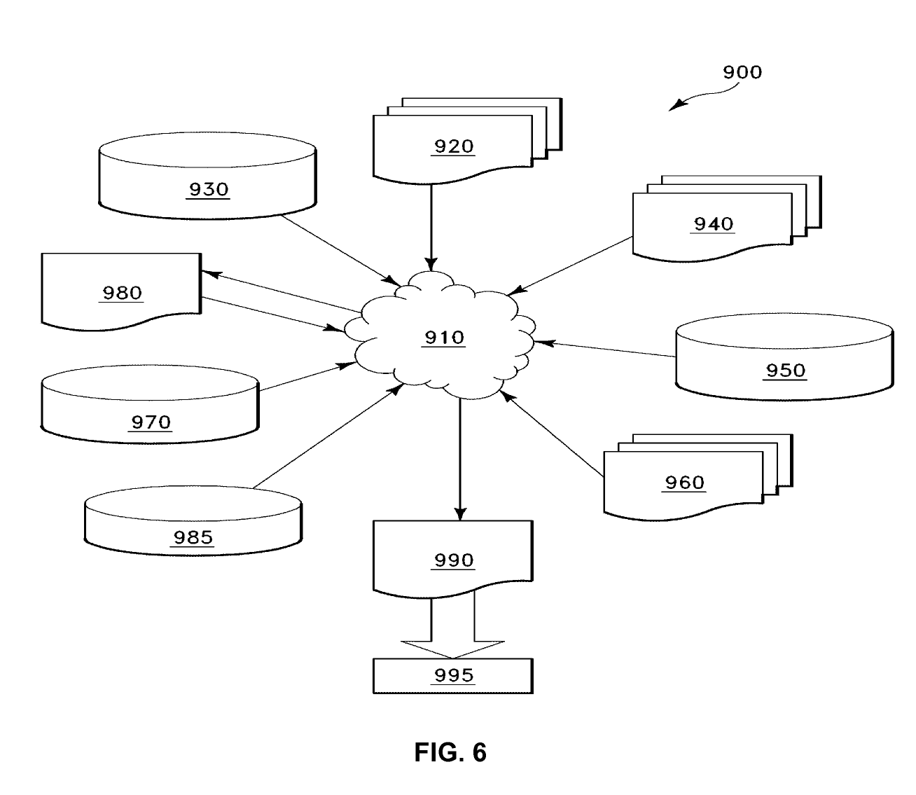

FIG. 6 shows a block diagram of an exemplary design flow 900 used for example, in semiconductor IC logic design, simulation, test, layout, and manufacture. Design flow 900 includes processes and mechanisms for processing design structures or devices to generate logically or otherwise functionally equivalent representations of the design structure and/or device described above and shown in FIG. 5. The design structure processed and/or generated by design flow 900 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems.

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA) offered by Altera® Inc. or Xilinx® Inc.

FIG. 6 illustrates multiple such design structures including an input design structure 920 that is preferably processed by a design process 910. In one embodiment, the design structure 920 comprises design data used in a design process and comprising information describing an embodiment of the invention with respect to the structure as shown in FIG. 5. The design data in the form of schematics or HDL, a hardware-description language (e.g., Verilog, VHDL, C, etc.) may be embodied on one or more machine readable media. For example, design structure 920 may be a text file, numerical data or a graphical representation of an embodiment of the invention, as shown in FIG. 5. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD) such as implemented by a core developer/designer. When encoded on a machine-readable data transmission, gate array, or storage medium, design structure 920 may be accessed and processed by one or more hardware and/or software modules within design process 910 to simulate or otherwise functionally represent an electronic component, circuit, electronic or logic module, apparatus, device, or system such as that shown in FIG. 5. As such, design structure 920 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 910 preferably employs and incorporates hardware and/or software modules for synthesizing, translating, or otherwise processing a design/simulation functional equivalent of the components, circuits, devices, or logic structures shown in FIG. 5 to generate a netlist 980 which may contain a design structure such as design structure 920. Netlist 980 may comprise, for example, compiled or otherwise processed data structures representing a list of wires, discrete components, logic gates, control circuits, I/O devices, models, etc. that describes the connections to other elements and circuits in an integrated circuit design. Netlist 980 may be synthesized using an iterative process in which netlist 980 is resynthesized one or more times depending on design specifications and parameters for the device. As with other design structure types described herein, netlist 980 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 910 may include hardware and software modules for processing a variety of input data structure types including netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985 which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990 comprising second design data embodied on a storage medium in a data format used for the exchange of layout data of integrated circuits and/or symbolic data format (e.g. information stored in a GDSII (GDS2), GL1, OASIS, map files, or any other suitable format for storing such design structures). In one embodiment, the second design data resides on a storage medium or programmable gate array in a data format used for the exchange of data of mechanical devices and structures (e.g. information stored in a IGES, DXF, Parasolid XT, JT, DRG, or any other suitable format for storing or rendering such mechanical design structures). Similar to design structure 920, design structure 990 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIG. 5. In one embodiment, design structure 990 may comprise a compiled, executable HDL simulation model that functionally simulates the device shown in FIG. 5.

Design structure 990 may also employ a data format used for the exchange of layout data of integrated circuits and/or symbolic data format (e.g. information stored in a GDSII (GDS2), GL1, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIG. 5. Design structure 990 may then proceed to a stage 995 where, for example, design structure 990: proceeds to tape-out, is released to manufacturing, is released to a mask house, is sent to another design house, is sent back to the customer, etc.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more described embodiment, the practical application or technical improvement over technologies found in the marketplace, or to enable others of ordinary skill in the art to understand the one or more embodiments disclosed herein.

What is claimed is:

1. A method of forming a semiconductor structure, the method comprising:
forming an epitaxial insulator layer over a substrate;
forming a semiconductor layer over the epitaxial insulator layer;
forming a fin structure at least partially from the semiconductor layer and on the epitaxial insulator layer; and
forming at least one epitaxial source-drain region having an embedded stressor on the epitaxial insulator layer and a side wall surface of the fin structure, the at least one epitaxial source-drain region having the embedded stressor providing stress along the fin structure.

2. The method of claim 1, further comprising:
forming a gate structure over the fin structure, wherein a channel is formed within a region of the fin structure that is located under the gate structure.

3. The method of claim 2, wherein the at least one epitaxial source-drain region having the embedded stressor generates a longitudinal stress along the direction of the formed channel.

4. The method of claim 1, wherein the at least one epitaxial source-drain region having the embedded stressor comprises a silicon germanium (SiGe) material for inducing a compressive stress with respect to the fin structure.

5. The method of claim 4, wherein the silicon germanium (SiGe) material comprises between about 10%-80% germanium.

6. The method of claim 1, wherein the at least one epitaxial source-drain region having the embedded stressor comprises a carbon (C) doped silicon (Si) material (Si:C) for inducing a tensile stress with respect to the fin structure.

7. The method of claim 6, wherein the carbon (C) doped silicon (Si) material comprises about 0.4%-3.0% carbon (C).

8. The method of claim 1, wherein the epitaxial insulator layer comprises a gadolinium oxide (Gd₂O₃) material.

9. The method of claim 1, wherein the epitaxial insulator layer comprises a strontium titanate (SrTiO₃) material.

10. The method of claim 1, wherein the epitaxial insulator layer comprises a barium titanate (BaTiO₃) material.

11. The method of claim 1, wherein the epitaxial insulator layer comprises an equivalent lattice constant to the substrate and semiconductor layer forming the fin.

12. The method claim 1, wherein forming a fin structure at least partially from the semiconductor layer comprises:
forming the fin entirely from the semiconductor layer.

13. The method claim 1, wherein forming a fin structure at least partially from the semiconductor layer comprises:
forming the fin both from the semiconductor layer and a portion of the epitaxial insulator layer, wherein the at least one epitaxial source-drain region having the embedded stressor is deposited in at least one recess formed within the epitaxial insulator layer.

14. A semiconductor structure comprising:
an epitaxial insulator layer located on a substrate;
a fin structure located on the epitaxial insulator layer; and
at least one epitaxial source-drain region having an embedded stressor located on the epitaxial insulator layer and abutting at least one sidewall associated with the fin structure, the at least one epitaxial source-drain region having the embedded stressor providing stress along the fin structure,
wherein the provided stress is generated between the at least one epitaxial source-drain region having the embedded stressor, and at least one of the epitaxial insulator layer and the at least one side-wall associated with the fin structure.

15. The semiconductor structure of claim 14, further comprising a gate structure including:
a gate dielectric located on a pair of sidewalls and a top surface of the fin structure; and
a gate electrode located on the gate dielectric.

16. The semiconductor structure of claim 15, further comprising at least one spacer that is operable to electrically isolate the gate structure from the at least one epitaxial source region having an embedded stressor.

17. The semiconductor structure of claim 14, wherein the at least one epitaxial source-drain region having the embedded stressor comprises:
a first epitaxial source region having an embedded stressor located on the epitaxial insulator layer and abutting a first sidewall associated with the fin structure; and
a second epitaxial source region having an embedded stressor located on the epitaxial insulator layer and abutting a second opposing sidewall associated with the fin structure,
wherein the first epitaxial source region is adjacent the second epitaxial source region.

18. The semiconductor structure of claim 17, wherein the at least one epitaxial source-drain region having the embedded stressor comprises:
a first epitaxial drain region having an embedded stressor located on the epitaxial insulator layer and abutting the first sidewall associated with the fin structure; and
a second epitaxial drain region having an embedded stressor located on the epitaxial insulator layer and abutting the second opposing sidewall associated with the fin structure,
wherein the first epitaxial drain region is adjacent the second epitaxial drain region, the first epitaxial drain region and the second epitaxial drain region separated from the first epitaxial source region and the second epitaxial source region by a gate structure located over the fin structure.

19. The semiconductor structure of claim 14, wherein the epitaxial insulator layer comprises a thickness having a range of about 5-1000 nanometers.

20. A design structure tangibly embodied in a machine readable medium for designing, manufacturing, or testing an integrated circuit, the design structure comprising:
an epitaxial insulator layer located on a substrate;
a fin structure located on the epitaxial insulator layer; and
at least one epitaxial source-drain region having an embedded stressor located on the epitaxial insulator layer and abutting at least one sidewall associated with the fin structure, the at least one epitaxial source-drain region having the embedded stressor providing stress along the fin structure,
wherein the provided stress is based on a lattice mismatch between the at least one epitaxial source-drain region having the embedded stressor, and both the epitaxial insulator layer and the at least one side-wall associated with the fin structure.
